(19) United States
(12) Patent Application Publication
(10) Pub. No.: US 2026/0304607 A1
(43) Pub. Date: Oct. 1, 2026

(54) WIRING BOARD AND METHOD FOR PRODUCING SAME

(71) Applicant: KYOCERA CORPORATION, Kyoto (JP)

(72) Inventors: Hirokazu NAKAI, Satsumasendai-shi, Kagoshima (JP); Noriyuki SHIMIZU, Satsumasendai-shi, Kagoshima (JP)

(73) Assignee: KYOCERA CORPORATION, Kyoto (JP)

(21) Appl. No.: 19/141,089

(22) PCT Filed: Dec. 12, 2023
(86) PCT No.: PCT/JP2023/044427

§ 371 Date: Jun. 4, 2026

(30) Foreign Application Priority Data
Dec. 20, 2022 (JP) 2022-203673
Feb. 28, 2023 (JP) 2023-029616

(51) Int. Cl. H05K 1/02; H05K 3/10; H05K 3/18

(52) U.S. Cl. CPC H05K 1/0298; H05K 3/107; H05K 3/188; H05K 2201/09036

(57) ABSTRACT

A wiring board includes a first insulating layer having first surface and second insulating layers, the second insulating layer having a second surface. First and second grooves are recessed from the second surface toward the first insulating layer and respectively include first and second inner surfaces. A first wiring conductor extends from the first groove to the first surface and includes a wide pattern having a width of at least 150 μm. The first wiring conductor includes a first underlying metal layer on the first surface, a first electrolytic plating layer on the first underlying metal layer with a side surface forming part of the first inner surface, a second underlying metal layer on the first inner surface connected to the side surface, and a second electrolytic plating layer filling the first groove. A second wiring conductor in the second groove includes a narrow pattern no greater than 15 μm.

### TECHNICAL FIELD

The present disclosure relates to a wiring board and a manufacturing method for the wiring board.

### BACKGROUND OF INVENTION

In known art, a semi-additive method has been used as a method for forming a wiring conductor in a wiring board. The semi-additive method is a method for forming a wiring conductor by the following procedure. First, a thin underlying metal layer is formed on an exposed surface of an insulating layer by an electroless plating method, a sputtering method, or the like. A plating resist layer including an opening portion corresponding to a pattern of the wiring conductor is formed on the underlying metal layer. An electrolytic plating layer is formed on the underlying metal layer exposed in the opening portion of the plating resist layer. After removing the plating resist layer by stripping, a portion of the underlying metal layer not covered with the electrolytic plating layer is removed by etching.

In wiring boards, miniaturization of wiring conductors has been progressing. In recent years, for example, there has been a demand for wiring boards in which the width of a wiring conductor is not more than 15 μm, and the interval between adjacent wiring conductors is not more than 15 μm. Thus, in wiring boards in which the width of a wiring conductor is relatively narrow (for example, not more than 15 μm), a bonding area between an insulating layer and a wiring conductor through the underlying metal layer becomes small. Therefore, the wiring conductor becomes likely to peel off from the insulating layer. The electrical insulation reliability between the wiring conductors adjacent to each other deteriorates.

As described in Patent Document 1, a method for forming a wiring conductor composed of an underlying metal layer and an electrolytic plating layer remaining in a groove has been proposed. First, the groove corresponding to a pattern of the wiring conductor is formed to a predetermined depth by a laser machining process on a surface of an insulating layer. A thin underlying metal layer is formed on the surface of the insulating layer including an inner surface of the groove by an electroless plating method, a sputtering method, or the like. An electrolytic plating layer having a thickness enough to fill the groove is formed on the underlying metal layer. Finally, the underlying metal layer and the electrolytic plating layer on the insulating layer are polished and removed by chemical mechanical polishing.

According to the method described in Patent Document 1, a groove for a wiring conductor having a relatively narrow width (for example, not more than 15 μm) is filled well with an electrolytic plating layer. However, a groove for the wiring conductor having a relatively wide width (for example, not less than 150 μm) is difficult to fill well with the electrolytic plating layer. As a result, in the wiring conductor having the wide width, the upper surface of the wiring conductor is significantly recessed and the flatness thereof becomes poor. In order to eliminate the recess, when a thickness of the electrolytic plating layer is further increased, stress generated when forming the electrolytic plating layer is increased. Thus, stress significantly acts, via the underlying metal layer, between the inner walls of the groove for the wiring conductor having the wide width, and the wiring conductor having the wide width becomes likely to peel off.

### CITATION LIST

### Patent Literature

Patent Document 1: JP 2004-149926 A

### SUMMARY

### Solution to Problem

A wiring board according to the present disclosure includes a first insulating layer including a first upper surface, a second insulating layer located on the first upper surface and including a second upper surface, a first groove and a second groove recessed from the second upper surface toward the first insulating layer, the first groove including a first inner surface, and the second groove including a second inner surface, a first wiring conductor located from the first groove to the first upper surface and including a wide pattern having a width of not less than 150 μm, and a second wiring conductor located in the second groove and including a narrow pattern having a width of not more than 15 μm. The first wiring conductor includes a first underlying metal layer located on the first upper surface, a first electrolytic plating layer located on the first underlying metal layer and including a side surface forming a portion of the first inner surface, a second underlying metal layer located on the first inner surface and connected to the side surface of the first electrolytic plating layer, and a second electrolytic plating layer located on the second underlying metal layer and filled into the first groove. The second wiring conductor includes a third underlying metal layer located on the second inner surface, and a third electrolytic plating layer located on the third underlying metal layer and filled into the second groove.

A method for manufacturing a wiring board according to the present disclosure includes forming a first insulating layer including a first upper surface, forming a wide pattern on the first upper surface, the wide pattern including a first underlying metal layer and a first electrolytic plating layer located on the first underlying metal layer, the wide pattern having a width of not less than 150 μm, forming a second insulating layer covering the first upper surface and the wide pattern, the second insulating layer including a second upper surface, forming a first groove and a second groove recessed from the second upper surface toward the first insulating layer side, the first groove including a first inner surface in contact with a side surface of the wide pattern, and the second groove including a second inner surface spaced apart from the wide pattern, forming a second underlying metal layer covering the first inner surface, a third underlying metal layer covering the second inner surface, a fourth underlying metal layer covering the second upper surface and being continuous with the second underlying metal layer and the third underlying metal layer, a second electrolytic plating layer located on the second underlying metal layer, the second electrolytic plating layer having a thickness to fill the first groove, a third electrolytic plating layer located on the third underlying metal layer, the third electrolytic plating layer having a thickness to fill the second groove, and a fourth electrolytic plating layer located on the fourth underlying metal layer and continuous with the second electrolytic plating layer and the third electrolytic plating layer, and forming a first wiring conductor located from the first groove to the first surface and including the wide pattern, a second wiring conductor located in the second groove and including a narrow pattern having a width of not more than 15 μm, by at least removing the fourth underlying metal layer and the fourth electrolytic plating layer located on the second upper surface.

### BRIEF DESCRIPTION OF THE DRAWINGS

FIG. 1 is an explanatory diagram illustrating a cross section of a wiring board according to a first embodiment of the present disclosure.

FIG. 2 is an explanatory diagram illustrating a manufacturing process of the wiring board according to the first embodiment of the present disclosure.

FIG. 3 is an explanatory diagram illustrating the manufacturing process of the wiring board according to the first embodiment of the present disclosure.

FIG. 4 is an explanatory diagram illustrating the manufacturing process of the wiring board according to the first embodiment of the present disclosure.

FIG. 5 is an explanatory diagram illustrating the manufacturing process of the wiring board according to the first embodiment of the present disclosure.

FIG. 6 is an explanatory diagram illustrating the manufacturing process of the wiring board according to the first embodiment of the present disclosure.

FIG. 7 is an explanatory diagram illustrating a cross section of a wiring board according to a second embodiment of the present disclosure.

FIG. 8 is an explanatory diagram illustrating a cross section of a wiring board according to a third embodiment of the present disclosure.

FIG. 9 is an explanatory diagram illustrating a cross section of a wiring board according to a fourth embodiment of the present disclosure.

FIG. 10 is a perspective view schematically illustrating only a conductor portion in the wiring board illustrated in FIG. 9.

FIG. 11 is an explanatory diagram illustrating a manufacturing process of the wiring board according to the fourth embodiment of the present disclosure.

FIG. 12 is an explanatory diagram illustrating the manufacturing process of the wiring board according to the fourth embodiment of the present disclosure.

FIG. 13 is an explanatory diagram illustrating the manufacturing process of the wiring board according to the fourth embodiment of the present disclosure.

FIG. 14 is an explanatory diagram illustrating the manufacturing process of the wiring board according to the fourth embodiment of the present disclosure.

FIG. 15 is an explanatory diagram illustrating the manufacturing process of the wiring board according to the fourth embodiment of the present disclosure.

### DESCRIPTION OF EMBODIMENTS

As described above, in the wiring board of the related art, a groove for a wiring conductor having a relatively narrow width (for example, not more than 15 μm) is filled well with an electrolytic plating layer. However, a groove for the wiring conductor having a relatively wide width (for example, not less than 150 μm) is difficult to fill well with the electrolytic plating layer. As a result, in the wiring conductor having the wide width, the upper surface of the wiring conductor is significantly recessed and the flatness thereof becomes poor. In order to eliminate the recess, when a thickness of the electrolytic plating layer is further increased, stress generated when forming the electrolytic plating layer is increased. Thus, stress significantly acts, via the underlying metal layer, between the inner walls of the groove for the wiring conductor having the wide width, and the wiring conductor having the wide width becomes likely to peel off. Therefore, a wiring board in which both a narrow wiring conductor and a wide wiring conductor are unlikely to be peeled off and the positioning accuracy between the narrow wiring conductor and the wide wiring conductor is high has been demanded.

The wiring board according to the present disclosure, by including a configuration as described in the section titled “SOLUTION TO PROBLEM”, allows both the narrow wiring conductor and the wide wiring conductor to be unlikely to be peeled off, and also provides high positioning accuracy between the narrow wiring conductor and the wide wiring conductor.

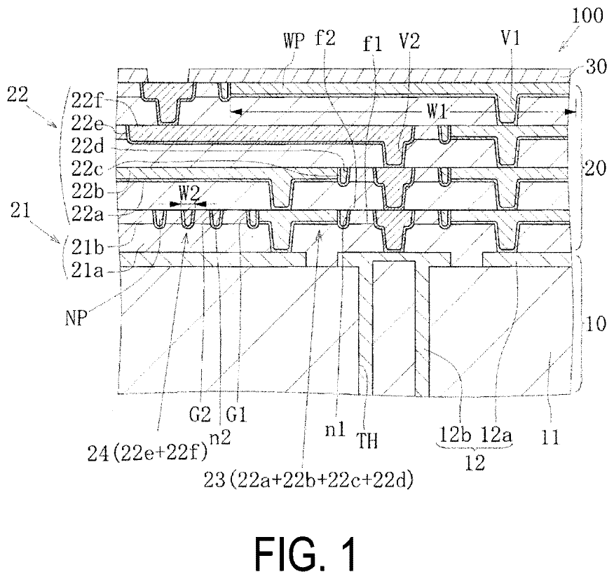

The wiring board of the present disclosure will be described with reference to drawings. FIG. 1 is a schematic diagram illustrating a portion of a cross section of a wiring board 100 according to a first embodiment of the present disclosure. The wiring board 100 according to the first embodiment includes a core substrate 10, a build-up layer 20 located on a surface of the core substrate 10, and a solder resist layer 30 located on a surface of the build-up layer 20. In FIG. 1, only a portion of an upper surface side of the wiring board 100 is illustrated.

The core substrate 10 includes a core insulating layer 11 and a core conductor 12. The core insulating layer 11 is made of a resin such as, for example, an epoxy resin, a bismaleimide-triazine resin, a polyimide resin, a polyphenylene ether resin, or a liquid crystal polymer. These resins may be used alone or two or more kinds may be used in combination. The core insulating layer 11 may contain a reinforcing material such as glass cloth, and may further contain insulating particles dispersed therein. The insulating particles are not limited, and examples thereof include inorganic insulating fillers such as, for example, silica, alumina, barium sulfate, talc, clay, glass, calcium carbonate, and titanium oxide. The core insulating layer 11 has a thickness of, for example, not less than 0.1 mm and not more than 2.0 mm.

The core conductor 12 includes a core conductor layer 12a and a through-hole conductor 12b. A core conductor layer 12a is located on upper and lower surfaces of the core insulating layer 11. The core conductor layer 12a is made of a conductor such as copper, for example, copper foil or copper plating. The thickness of the core conductor layer 12a is not particularly limited, and is, for example, not less than 5 μm and not more than 50 μm.

The through-hole conductor 12b is located in a through hole TH that penetrates the core insulating layer 11 vertically. The through-hole conductor 12b electrically connects the core conductor layers 12a located on the upper and lower surfaces of the core insulating layer 11. The through-hole conductor 12b is a conductor made of metal plating such as copper plating, for example. The through-hole conductor 12b is integrally connected to the core conductor layers 12a on both surfaces of the core insulating layer 11. The through-hole conductor 12b may be formed only on an inner wall surface of the through hole TH, or may be filled into the through hole TH.

The build-up layer 20 includes a build-up insulating layer 21 and a build-up conductor layer 22. The build-up insulating layer 21 includes a first insulating layer 21a including a first upper surface f1, and a second insulating layer 21b located on the first upper surface f1 of the first insulating layer 21a and including a second upper surface f2. The first insulating layer 21a is made of a resin such as, for example, an epoxy resin, a bismaleimide-triazine resin, a polyimide resin, a polyphenylene ether resin, or a liquid crystal polymer. These resins may be used alone or two or more kinds may be used in combination. The first insulating layer 21a may contain insulation particles dispersed therein. The insulation particles are not limited, and examples thereof include inorganic insulation fillers such as, for example, silica, alumina, barium sulfate, talc, clay, glass, calcium carbonate, and titanium oxide. The first insulating layer 21a has a thickness of, for example, not less than 10 μm and not more than 50 μm.

The second insulating layer 21b is located on the first upper surface f1 of the first insulating layer 21a. Examples of the resins for the second insulating layer 21b include resins the same as and/or similar to resins forming the above-described first insulating layer 21a, and the resins may be used alone or two or more kinds may be used in combination. The second insulating layer 21b may also have insulating particles the same as and/or similar to those of the first insulating layer 21a dispersed therein. The thickness of the second insulating layer 21b is not limited, and may be, for example, less than a thickness of the first insulating layer 21a. The second insulating layer 21b has a thickness of, for example, not less than 5 μm and not more than 25 μm.

The core insulating layer 11, the first insulating layer 21a, and the second insulating layer 21b may be made of the same resin, or may be made of different resins. When insulating particles are dispersed in the core insulating layer 11, the first insulating layer 21a, and the second insulating layer 21b, the insulating particles may be the same or different.

The build-up conductor layer 22 includes a first underlying metal layer 22a, a first electrolytic plating layer 22b, a second underlying metal layer 22c, a second electrolytic plating layer 22d, a third underlying metal layer 22e, and a third electrolytic plating layer 22f. The first underlying metal layer 22a is located on the first upper surface f1 of the first insulating layer 21a. The first underlying metal layer 22a is made of, for example, a metal such as copper. The first underlying metal layer 22a has a thickness of, for example, not less than 0.1 μm and not more than 0.5 μm. As illustrated in FIG. 1, the first underlying metal layer 22a may be located on an inner surface of a via hole V1 that penetrates the first insulating layer 21a. The first underlying metal layer 22a serves to improve the adhesiveness of the first electrolytic plating layer 22b.

The first electrolytic plating layer 22b is located on the first underlying metal layer 22a. The first electrolytic plating layer 22b is not limited, provided that the layer is formed by the electrolytic plating, and is made of a metal such as copper, for example. The first electrolytic plating layer 22b has a thickness of, for example, not less than 5 μm and not more than 25 μm.

The second underlying metal layer 22c is located on a first inner surface n1 of a first groove G1 recessed from the second upper surface f2 of the second insulating layer 21b toward the first insulating layer 21a. The first groove G1 is in contact with a side surface of the first electrolytic plating layer 22b. That is, the side surface of the first electrolytic plating layer 22b forms a portion of the first inner surface n1 of the first groove G1. The second underlying metal layer 22c is made of, for example, a metal such as copper. The second underlying metal layer 22c has a thickness of, for example, not less than 0.1 μm and not more than 0.5 μm. The second underlying metal layer 22c serves to improve the adhesiveness of the second electrolytic plating layer 22d.

The second electrolytic plating layer 22d is filled into the first groove G1 in which the second underlying metal layer 22c is formed. The second electrolytic plating layer 22d is not limited, provided that the layer is formed by the electrolytic plating, and is made of a metal such as copper, for example. Both the side surface and the bottom surface of the second electrolytic plating layer 22d are located in the first groove G1 with the second underlying metal layer 22c interposed therebetween. Therefore, excellent adhesion strength is exhibited, and peeling of the second electrolytic plating layer 22d can be reduced.

The third underlying metal layer 22e is located on a second inner surface n2 of a second groove G2 recessed from the second upper surface f2 of the second insulating layer 21b toward the first insulating layer 21a. The third underlying metal layer 22e is made of, for example, a metal such as copper. The third underlying metal layer 22e has a thickness of, for example, not less than 0.1 μm and not more than 0.5 μm. As illustrated in FIG. 1, the third underlying metal layer 22e may be located on an inner surface of a via hole V2 that penetrates the first insulating layer 21a. The third underlying metal layer 22e serves to improve the adhesiveness of the third electrolytic plating layer 22f.

The third electrolytic plating layer 22f is filled into the second groove G2 in which the third underlying metal layer 22e is formed. The third electrolytic plating layer 22f is not limited, provided that the layer is formed by the electrolytic plating, and is made of a metal such as copper, for example. Both the side surface and the bottom surface of the third electrolytic plating layer 22f are located in the second groove G2 with the third underlying metal layer 22e interposed therebetween. Therefore, excellent adhesion strength is exhibited, and peeling of the third electrolytic plating layer 22f can be reduced.

The build-up conductor layer 22 includes a first wiring conductor 23 and a second wiring conductor 24 having different widths. The first wiring conductor 23 includes a wide pattern WP having a width W1 of not less than 150 μm. On the other hand, the first wiring conductor 23 does not include a pattern having a width of not more than 15 μm. The first wiring conductor 23 is constituted by the first underlying metal layer 22a and the first electrolytic plating layer 22b on the first insulating layer 21a, and the second underlying metal layer 22c and the second electrolytic plating layer 22d in the first groove G1. The first wiring conductor 23 mainly has functions for grounding and power supply. The width W1 can be defined as a length between mutually opposing sides, for example, in the first wiring conductor 23.

In the first wiring conductor 23, the second underlying metal layer 22c and the second electrolytic plating layer 22d of the first groove G1 are located between the side surface of the first electrolytic plating layer 22b and the second insulating layer 21b. That is, the side surface of the first electrolytic plating layer 22b constituting the first wiring conductor 23 is not in contact with the second insulating layer 21b. Therefore, since the side surface of the first electrolytic plating layer 22b is not in contact with the second insulating layer 21b, stresses directly transmitted to the second insulating layer 21b between the side surface of the first electrolytic plating layer 22b and the second insulating layer 21b can be eliminated. As a result, peeling of the first electrolytic plating layer 22b can be reduced.

In the first electrolytic plating layer 22b, an arithmetic mean roughness Ra of a side surface is not limited and may be, for example, not less than 150 nm and not more than 300 nm. In the first electrolytic plating layer 22b, when the arithmetic mean roughness Ra of the side surface is not less than 150 nm and not more than 300 nm, the side surface of the first electrolytic plating layer 22b is firmly adhered to the second underlying metal layer 22c of the first inner surface n1 of the first groove G1, and peeling of the first electrolytic plating layer 22b can be further reduced.

The second underlying metal layer 22c and the second electrolytic plating layer 22d of the first groove G1 have a function of protecting the first electrolytic plating layer 22b from peeling and improving the positioning accuracy between the first wiring conductor 23 and the second wiring conductor 24. The width of the first groove G1 is not limited, and may be, for example, approximately not less than 5 μm and not more than 100 μm. The depth of the first groove G1 is not limited and may be, for example, approximately not less than 5 μm and not more than 75 μm. The width of the first groove G1 can be defined by, for example, a length between the opening edges of the first groove G1 facing each other in the second insulating layer 21b. The depth of the first groove G1 can be defined by, for example, a length from a position at the same height as the second upper surface f2 in the opening of the first groove G1 to a position of the first groove G1 closest to the core substrate 10.

An arithmetic mean roughness Ra other than a side surface of the first electrolytic plating layer 22b in the first inner surface n1 of the first groove G1 is not limited, and may be, for example, not less than 50 nm and not more than 100 nm. When an arithmetic mean roughness Ra other than the side surface of the first electrolytic plating layer 22b in the first inner surface n1 of the first groove G1 is not less than 50 nm and not more than 100 nm, the second underlying metal layer 22c is firmly adhered to the first inner surface n1 in the first groove G1, and peeling of the second underlying metal layer 22c can be further reduced.

The second wiring conductor 24 is constituted by the third underlying metal layer 22e and the third electrolytic plating layer 22f of the second groove G2. The second wiring conductor 24 includes a narrow pattern NP having a width W2 of not more than 15 μm. On the other hand, the second wiring conductor 24 does not include a pattern having a width of not less than 150 μm. A depth of the second groove G2 is not limited and may be, for example, not less than 5 μm and not more than 25 μm. The second wiring conductor 24 mainly has a function for signal transmission. In FIG. 1, the second wiring conductor 24, which appears to be wide, is present. However, the second wiring conductor 24 that appears to be wide is illustrated as a cross section cut in a longitudinal direction. The width W2 can be defined as, for example, the shortest length between sides facing each other in the second wiring conductor 24. The depth of the second groove G2 can be defined by, for example, a length from a position at the same height as the second upper surface f2 in the opening of the second groove G2 to a position of the second groove G2 closest to the core substrate 10.

An arithmetic mean roughness Ra of the second inner surface n2 of the second groove G2 is not limited, and may be, for example, not less than 50 nm and not more than 100 nm. When the arithmetic mean roughness Ra of the second inner surface n2 of the second groove G2 is not less than 50 nm and not more than 100 nm, the third underlying metal layer 22e is more firmly adhered to the second inner surface n2 of the second groove G2, and peeling of the third underlying metal layer 22e can be further reduced. The second wiring conductor 24 has surface roughness with the arithmetic mean roughness Ra of not less than 50 nm and not more than 100 nm, corresponding to the roughness of the second inner surface n2 of the second groove G2. This roughness is less, and is advantageous in that transmission loss can be reduced when a high-frequency signal is transmitted through the second wiring conductor 24.

The solder resist layer 30 is located on the build-up layer 20. The solder resist layer 30 is made of, for example, an acrylic-modified epoxy resin. The solder resist layer 30 has a function of protecting an electrical conductor layer and the like from solder when, for example, an electronic component is mounted or connected to a motherboard or the like. The solder resist layer 30 includes an opening portion for exposing a portion of the first wiring conductor 23 or the second wiring conductor 24 located on the surface of the build-up layer 20. A portion of the first wiring conductor 23 or the second wiring conductor 24 exposed from the opening portion functions as a pad when mounting a semiconductor element or the like.

A method for manufacturing a wiring board of the present disclosure will be described. The manufacturing method for the wiring board according to the present disclosure includes the following steps (a) to (f).
(a) forming a first insulating layer including a first upper surface.
(b) forming a wide pattern on the first upper surface, the wide pattern having a width W1 of not less than 150 μm and including a first underlying metal layer and a first electrolytic plating layer located on the first underlying metal layer.
(c) forming a second insulating layer covering the first upper surface and the wide pattern and including a second upper surface.
(d) forming a first groove and a second groove recessed from the second upper surface toward the first insulating layer, the first groove including a first inner surface and in contact with a side surface of the wide pattern, and the second groove including a second inner surface spaced apart from the wide pattern.
(e) forming a second underlying metal layer covering the first inner surface, a third underlying metal layer covering the second inner surface, a fourth underlying metal layer covering the second upper surface and being continuous with the second underlying metal layer and the third underlying metal layer, a second electrolytic plating layer located on the second underlying metal layer and having a thickness to fill the first groove, a third electrolytic plating layer having a thickness to fill the second groove, and a fourth electrolytic plating layer located on the fourth underlying metal layer and continuous with the second electrolytic plating layer and the third electrolytic plating layer.
(f) forming a first wiring conductor including the wide pattern located from the first groove to the first upper surface and forming a second wiring conductor including a narrow pattern having the width W2 of not more than 15 μm and located in the second groove, by at least removing the fourth underlying metal layer and the fourth electrolytic plating layer located on the second upper surface.

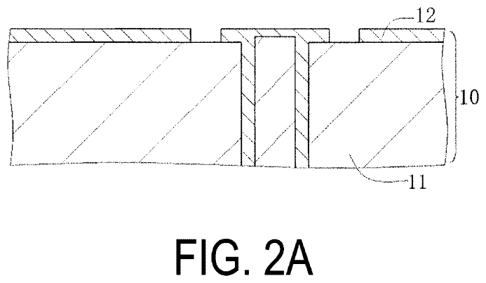

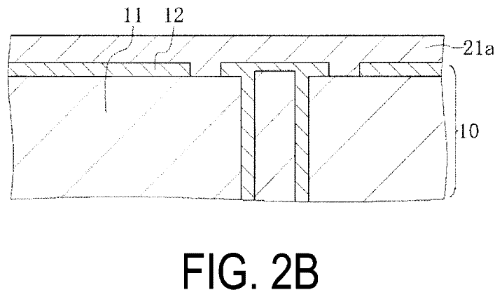

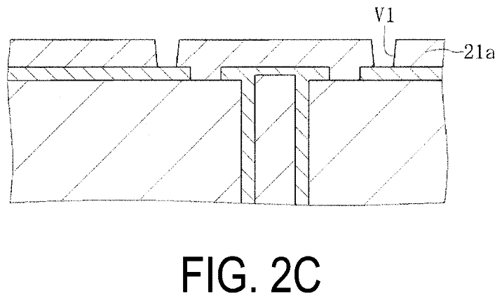

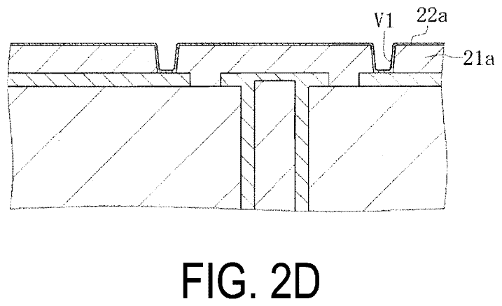

A manufacturing method for the wiring board according to the present disclosure will be described with reference to FIGS. 2 to 6. FIGS. 2 to 6 are explanatory diagrams illustrating manufacturing processes for the wiring board 100 according to the first embodiment.

First, as illustrated in FIG. 2A, the core substrate 10 is prepared. The core substrate 10 includes the core insulating layer 11 and the core conductor 12. The core insulating layer 11 and the core conductor 12 are as described above, and thus detailed description thereof is omitted.

The step (step (a)) of forming the first insulating layer will be described. As illustrated in FIG. 2B, the first insulating layer 21a is formed so as to cover the core insulating layer 11 and the core conductors 12 of the core substrate 10. The first insulating layer 21a is as described above, and thus detailed description thereof is omitted. The first insulating layer 21a is formed by, for example, laminating a thermosetting resin sheet for the first insulating layer 21a on the core substrate 10 and thermally curing the thermosetting resin sheet by applying pressure and heat from above and below. As illustrated in FIG. 2C, the via hole V1 is formed in the first insulating layer 21a as necessary. The via hole V1 is formed by a laser machining process such as a CO₂ laser, a UV-YAG laser, and an excimer laser, for example.

The step (step (b)) of forming a wide pattern on the upper surface of the first insulating layer 21a, the wide pattern including a first underlying metal layer and a first electrolytic plating layer located on the first underlying metal layer and having a width of not less than 150 μm will be described. As illustrated in FIG. 2D, the first underlying metal layer 22a such as copper is deposited on the upper surface of the first insulating layer 21a and the inner surface of the via hole V1 by electroless plating. When performing the electroless plating, palladium may be used as a catalyst. The deposited first underlying metal layer 22a has a thickness of, for example, not less than 0.1 μm and not more than 0.5 μm.

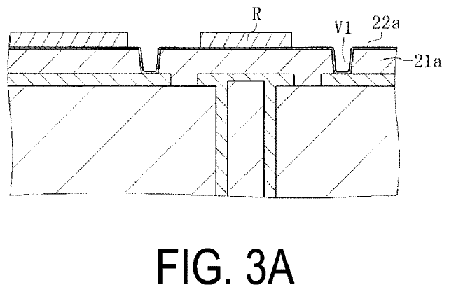

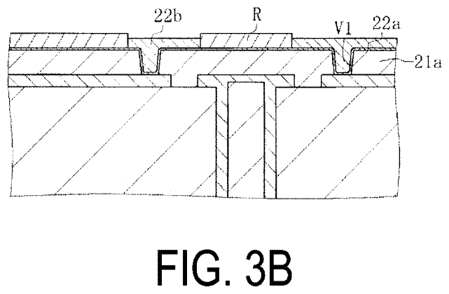

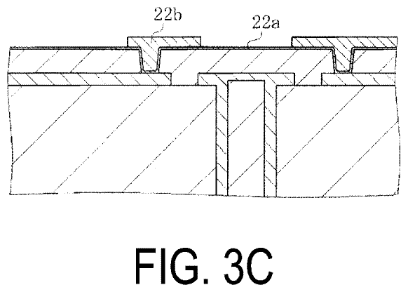

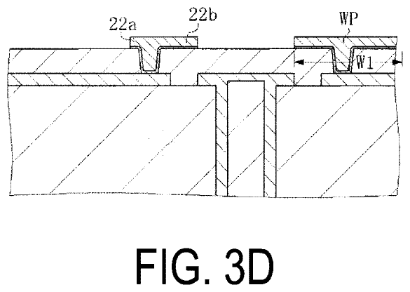

After the first underlying metal layer 22a such as copper is deposited by the electroless plating, as illustrated in FIG. 3A, a portion where the first electrolytic plating layer 22b is not formed is covered with a resist R. After being covered with the resist R, as illustrated in FIG. 3B, a first electrolytic plating layer 22b of copper or the like is deposited by the electrolytic plating. The first electrolytic plating layer 22b has a thickness of, for example, not less than 5 μm and not more than 25 μm. By setting the width of the portion where the first electrolytic plating layer 22b is deposited to not less than 150 μm, a wide pattern can be formed. Then, the resist R is removed as illustrated in FIG. 3C, and the first underlying metal layer 22a of the portion covered with the resist R is removed as illustrated in FIG. 3D.

In this manner, the wide pattern WP having the width W1 of not less than 150 μm and constituted by the first underlying metal layer 22a and the first electrolytic plating layer 22b located on the first underlying metal layer 22a is formed on the first insulating layer 21a.

A roughening treatment may be performed on the side surface of the first electrolytic plating layer 22b so that the arithmetic mean roughness Ra becomes not less than 150 nm and not more than 300 nm. By performing such a roughening treatment, the second underlying metal layer 22c described below is firmly adhered to the side surface of the first electrolytic plating layer 22b, and peeling of the first electrolytic plating layer 22b can be further reduced.

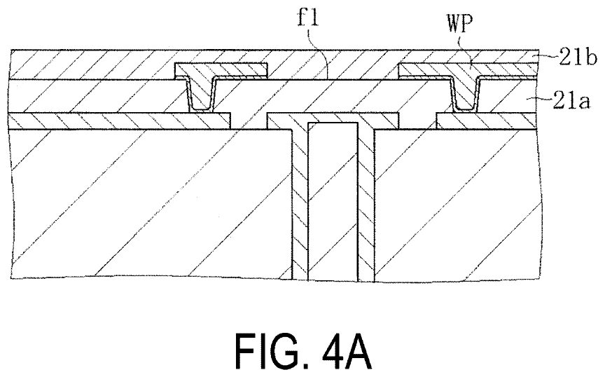

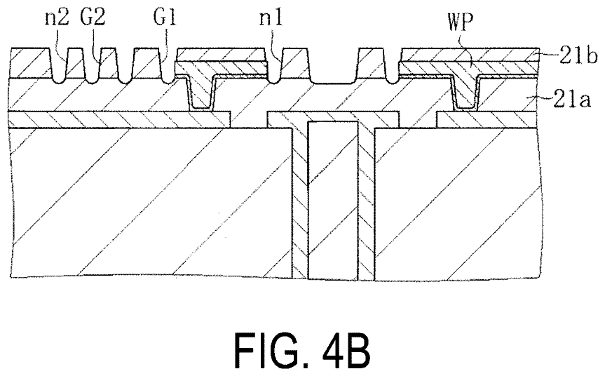

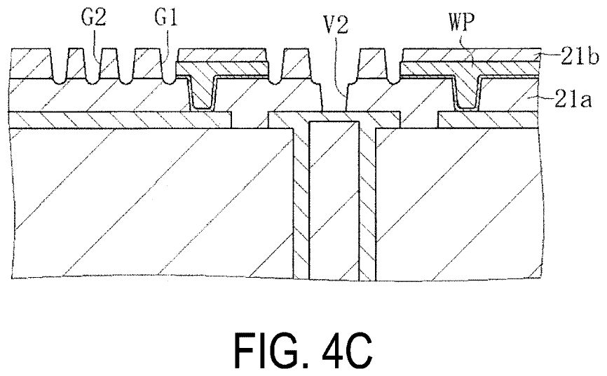

The step (step (c)) of forming the second insulating layer covering the upper surface of the first insulating layer and the wide pattern will be described. As illustrated in FIG. 4A, the second insulating layer 21b is formed so as to cover the first upper surface f1 of the first insulating layer 21a and the wide pattern WP. The second insulating layer 21b is formed by, for example, laminating a thermosetting resin sheet for the second insulating layer 21b on the first upper surface f1 of the first insulating layer 21a and the wide pattern WP and thermally curing the thermosetting resin sheet by applying pressure and heat from above and below.

The step (step (d)) of forming the first groove and the second groove recessed from the upper surface of the second insulating layer toward the first insulating layer, the first groove including the first inner surface and in contact with the side surface of the wide pattern, and the second groove including the second inner surface spaced apart from the wide pattern will be described. As illustrated in FIG. 4B, the first groove G1 including the first inner surface n1 located at a position in contact with a side surface of the wide pattern WP is formed in the second insulating layer 21b, and the second groove G2 including the second inner surface n2 located apart from the side surface of the wide pattern WP at a position where the second wiring conductor 24 is to be formed is formed. A method for forming the first groove G1 and the second groove G2 is not limited, and the grooves are formed by a laser machining process using an excimer laser, a CO₂ laser, a UV-YAG laser, or the like. An excimer laser is preferably employed from the viewpoint of ease of forming the first groove G1 and the second groove G2 having uniform depths. The depths of the first groove G1 and the second groove G2 are not limited and may be, for example, not less than 5 μm and not more than 25 μm. As illustrated in FIG. 4C, the via hole V2 may be formed in the first insulating layer 21a as necessary. The via hole V2 may be formed by a laser machining process using an excimer laser, a CO₂ laser, a UV-YAG laser, or the like.

When the first groove G1 and the second groove G2 are formed, the groove forming process may be performed in which the first inner surface n1 of the first groove G1 and the second inner surface n2 of the second groove G2, excluding the side surface of the wide pattern WP, have an arithmetic mean roughness Ra of not less than 50 nm and not more than 100 nm. Also in this case, the use of an excimer laser facilitates the formation of the inner surface with a predetermined roughness. When the first groove G1 and the second groove G2 are formed in this manner, the second underlying metal layer 22c and the third underlying metal layer 22e are firmly adhered to the first insulating layer 21a and the second insulating layer 21b, peeling of the second underlying metal layer 22c and the third underlying metal layer 22e can be further reduced.

The step (step (e)) of forming a second underlying metal layer covering the first inner surface, a third underlying metal layer covering the second inner surface, a fourth underlying metal layer covering the second upper surface and being continuous with the second underlying metal layer and the third underlying metal layer, a second electrolytic plating layer located on the second underlying metal layer and having a thickness to fill the first groove, a third electrolytic plating layer located on the third underlying metal layer and having a thickness to fill the second groove, and a fourth electrolytic plating layer located on the fourth underlying metal layer and continuous with the second electrolytic plating layer and the third electrolytic plating layer will be described.

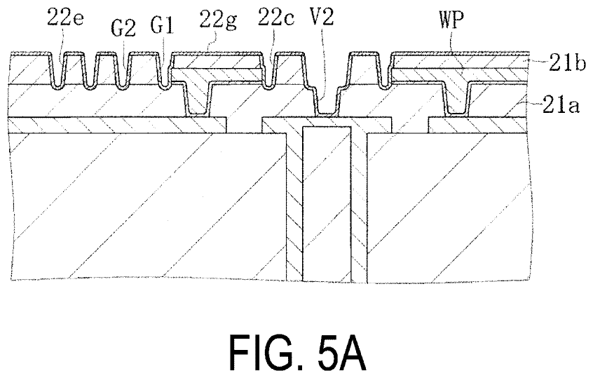

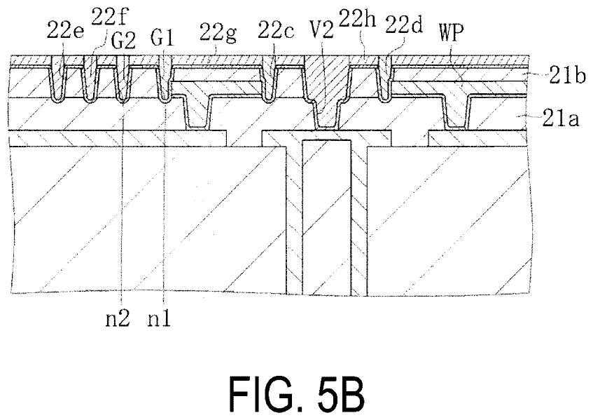

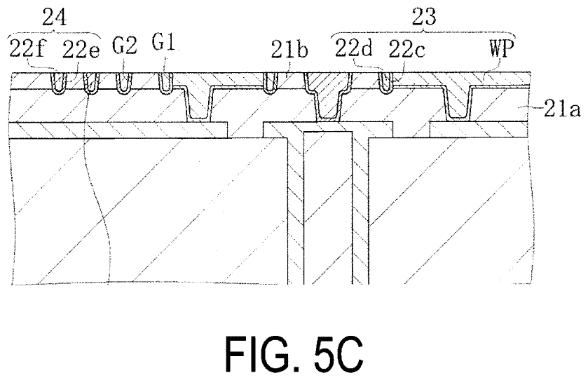

As illustrated in FIG. 5A, the second underlying metal layer 22c covering the first inner surface n1, the third underlying metal layer 22e covering the second inner surface n2, and a fourth underlying metal layer 22g covering the second upper surface f2 and being continuous with the second underlying metal layer 22c and the third underlying metal layer 22e are formed. The second underlying metal layer 22c, the third underlying metal layer 22e, and the fourth underlying metal layer 22g are formed simultaneously, for example, by depositing a metal such as copper by the electroless plating. In other words, the second underlying metal layer 22c, the third underlying metal layer 22e, and the fourth underlying metal layer 22g are metal layers formed by the same electroless plating process. When performing the electroless plating, palladium may be used as a catalyst. The second underlying metal layer 22c, the third underlying metal layer 22e, and the fourth underlying metal layer 22g have thicknesses of, for example, not less than 0.1 μm and not more than 0.5 μm, and are also formed on the inner surface of the via hole V2.

After forming the second underlying metal layer 22c, the third underlying metal layer 22e, and the fourth underlying metal layer 22g, as illustrated in FIG. 5B, a second electrolytic plating layer 22d located on the second underlying metal layer 22c and having a thickness fill the first groove G1, a third electrolytic plating layer 22f located on the third underlying metal layer 22e and having a thickness to fill the second groove G2, and a fourth electrolytic plating layer 22h located on the fourth underlying metal layer 22g and continuous with the second electrolytic plating layer 22d and the third electrolytic plating layer 22f are formed. The second electrolytic plating layer 22d, the third electrolytic plating layer 22f, and the fourth electrolytic plating layer 22h are simultaneously formed using a metal such as copper, for example. In other words, the second electrolytic plating layer 22d, the third electrolytic plating layer 22f, and the fourth electrolytic plating layer 22h are plating layers formed by the same electrolytic plating process.

The step (step (f)) of forming the first wiring conductor located from the first groove to the first upper surface f1 and including the wide pattern and forming the second wiring conductor located in the second groove and including the narrow pattern having a width of not more than 15 μm by removing at least the fourth underlying metal layer and the fourth electrolytic plating layer located on the second insulating layer will be described.

As illustrated in FIG. 5C, at least the fourth underlying metal layer 22g and the fourth electrolytic plating layer 22h located on the second insulating layer 21b are removed. In this removing step, a portion of the second insulating layer 21b may be removed as necessary. For example, when the width of the second groove G2 near the opening portion exceeds 15 μm, a portion of the second insulating layer 21b may be removed, including the fourth underlying metal layer 22g and the fourth electrolytic plating layer 22h located on the second insulating layer 21b, until the width of the second groove G2 becomes not more than 15 μm. In this manner, the first wiring conductor 23 including the wide pattern WP and the second underlying metal layer 22c and the second electrolytic plating layer 22d remaining in the first groove G1 are formed, and the second wiring conductor 24 including the narrow pattern NP having a width of not more than 15 μm and including the third underlying metal layer 22e and the third electrolytic plating layer 22f remaining in the second groove G2 are formed.

As described above, the first groove G1 in contact with the side surface of the wide pattern WP constituting the first wiring conductor 23 and the second groove G2 spaced apart from the wide pattern WP are formed in the same step (step (d)). After the second electrolytic plating layer 22d having a thickness to fill the first groove G1 and the third electrolytic plating layer 22f having a thickness to fill the second groove G2 are formed in the step (step (e)), at least the fourth underlying metal layer 22g and the fourth electrolytic plating layer 22h located on the second insulating layer 21b are removed in the step (step (f)). In this manner, the first wiring conductor 23, which extends from the first groove G1 to the first upper surface f1 and includes the wide pattern WP, is formed, and the second wiring conductor 24, which is located in the second groove G2 and includes the narrow pattern NP having the width W2 of not more than 15 μm, is formed. As a result, the positioning accuracy between the first wiring conductor 23 and the second wiring conductor 24 can be made high.

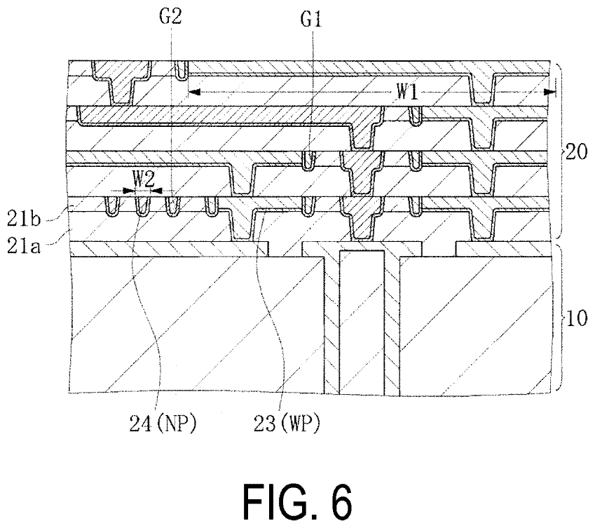

By repeating the steps (a) to (f), as illustrated in FIG. 6, the build-up layer 20 including a desired number of layers is formed on the core substrate 10. As described above, the build-up layer 20 includes the first insulating layer 21a, the second insulating layer 21b located on the first upper surface f1 of the first insulating layer 21a, the first groove G1 and the second groove G2 recessed from the second upper surface f2 of the second insulating layer 21b toward the first insulating layer 21a, the first wiring conductor 23 located from the first groove G1 to the first upper surface f1 of the first insulating layer 21a and including the wide pattern WP having the width W1 of not less than 150 μm, and the second wiring conductor 24 located in the second groove G2 and including the narrow pattern NP having the width W2 of not more than 15 μm.

Finally, the solder resist layer 30 is formed so as to be located on the surface of the build-up layer 20, thereby obtaining the wiring board 100 illustrated in FIG. 1. The solder resist layer 30 is formed by covering the surface of the build-up layer with a film made of, for example, an acrylic-modified epoxy resin, and curing the film. The solder resist layer 30 is as described above, and thus detailed description thereof is omitted.

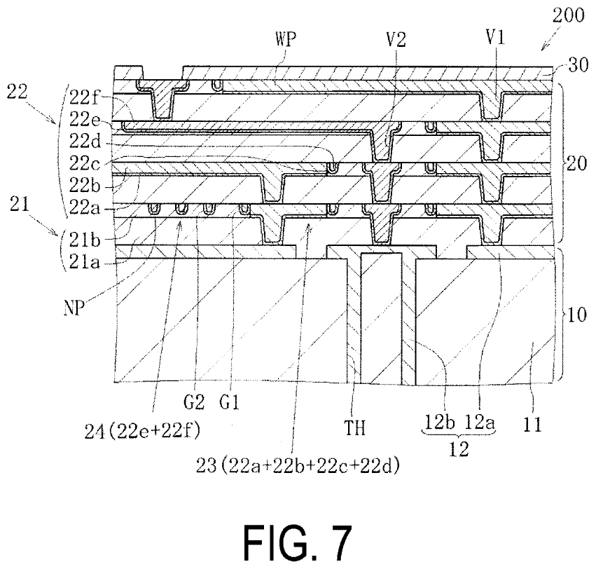

A wiring board according to another embodiment of the present disclosure will be described with reference to FIG. 7. FIG. 7 is an explanatory diagram illustrating a cross section of a wiring board 200 according to a second embodiment of the present disclosure. In the wiring board 200 illustrated in FIG. 7, components the same as and/or similar to those of the wiring board 100 according to the first embodiment are denoted by the same reference signs, and detailed description is omitted.

In the wiring board 100 according to the first embodiment, the bottom surface of the second wiring conductor 24 (the bottom surface of the third underlying metal layer 22e) is in contact with the first insulating layer 21a. On the other hand, in the wiring board 200 according to the second embodiment, a bottom surface of a second wiring conductor 24 (a bottom surface of a third underlying metal layer 22e) are not in contact with a first insulating layer 21a. That is, the second wiring conductor 24 (the third underlying metal layer 22e and a third electrolytic plating layer 22f) are accommodated within a second insulating layer 21b. In other words, the depth of the second groove G2 is less than the thickness of the second insulating layer 21b. As described above, the wiring board 200 according to the second embodiment differs from the wiring board 100 according to the first embodiment in the arrangement of the second wiring conductor 24.

When palladium is used as a catalyst in forming a first underlying metal layer 22a, a second underlying metal layer 22c, the third underlying metal layer 22e, and a fourth underlying metal layer 22g by the electroless plating, palladium may remain. When palladium remains, migration is likely to occur near the boundary between the first insulating layer 21a and the second insulating layer 21b between the second wiring conductors 24 (the third underlying metal layers 22e) adjacent to each other or between the second wiring conductor 24 and a first wiring conductor 23. When the second wiring conductor 24 is accommodated within the second insulating layer 21b as in the wiring board 200 according to the second embodiment, the third underlying metal layer 22e is separated from the boundary between the first insulating layer 21a and the second insulating layer 21b. As a result, migration in the vicinity of the boundary can be reduced, and insulation reliability is further improved.

In the method for manufacturing the wiring board 200 according to the second embodiment, for example, in the step (step (d)) of forming the first groove G1 and the second groove G2 described above, a depth of the second groove G2 may be adjusted so that a bottom surface of the second groove G2 is accommodated within the second insulating layer 21b. That is, the second groove G2 is formed to have the depth less than the thickness of the second insulating layer 21b. The depth of the second groove G2 is appropriately set in accordance with the thickness of the second insulating layer 21b.

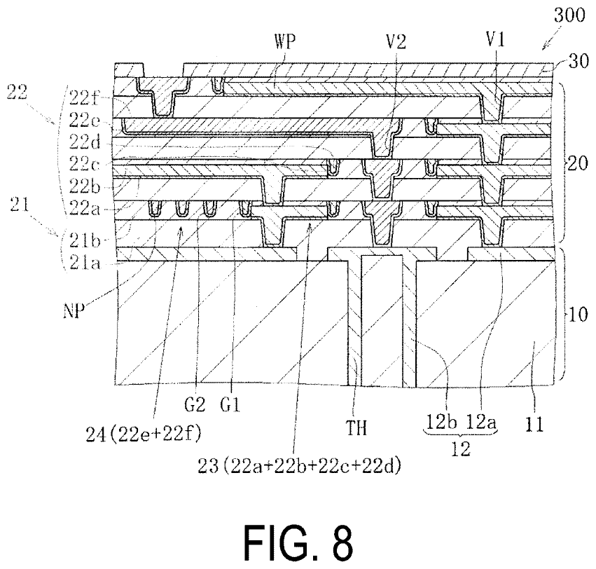

A wiring board according to still another embodiment of the present disclosure will be described with reference to FIG. 8. FIG. 8 is an explanatory diagram illustrating a cross section of a wiring board 300 according to a third embodiment of the present disclosure. In the wiring board 300 illustrated in FIG. 8, components the same as and/or similar to those of the wiring board 100 according to the first embodiment are denoted by the same reference signs, and detailed description is omitted.

In the wiring board 100 according to the first embodiment, the upper surface of the first wiring conductor 23 (the upper surface of the first electrolytic plating layer 22b) is not covered with the second insulating layer 21b. On the other hand, in the wiring board 300 according to the third embodiment, at least a portion of an upper surface of a first wiring conductor 23 (an upper surface of a first electrolytic plating layer 22b) is covered with a second insulating layer 21b without being exposed from the second insulating layer 21b. As described above, the wiring board 300 according to the third embodiment differs from the wiring board 100 according to the first embodiment in the arrangement of the first wiring conductor 23.

For example, a slight gap may exist near the boundary between the second insulating layer 21b and the insulating layer located thereon, and migration may occur in a case in which the wiring conductors adjacent to each other are exposed at the boundary. That is, migration is likely to occur near the boundary between the first wiring conductor 23 (the first electrolytic plating layer 22b) and the second insulating layer 21b. When at least a portion of the upper surface of the first wiring conductor 23 is covered with the second insulating layer 21b as in the wiring board 300 according to the third embodiment, the upper surface of the first electrolytic plating layer 22b is separated from the boundary between the upper surface of the second insulating layer 21b and the insulating layer located thereon. As a result, migration can be reduced between the upper surface of the first electrolytic plating layer 22b and the upper surface of the second insulating layer 21b, and insulation reliability is further improved.

In the method for manufacturing the wiring board 300 according to the third embodiment, for example, in the step (step (f)) of forming the second wiring conductor described above, at least a fourth underlying metal layer 22g and a fourth electrolytic plating layer 22h located on the second insulating layer 21b may be removed so that at least a portion of the upper surface of the first wiring conductor 23 is not exposed. The vicinity of the upper surface of the second insulating layer 21b may be removed as necessary.

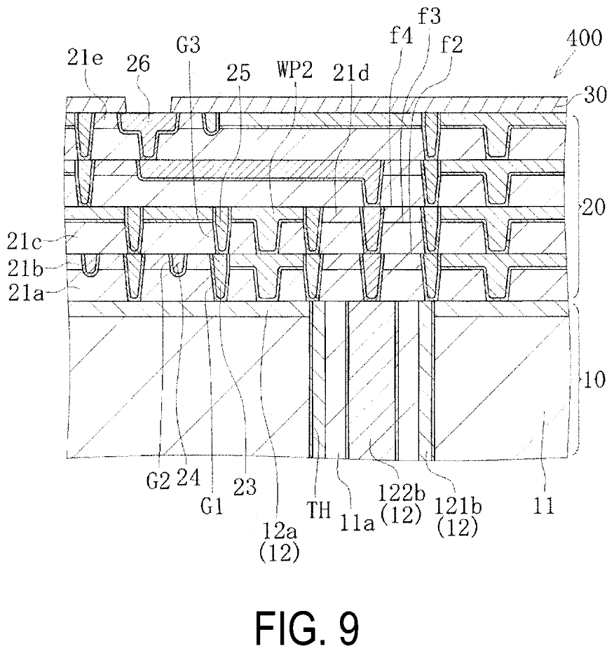

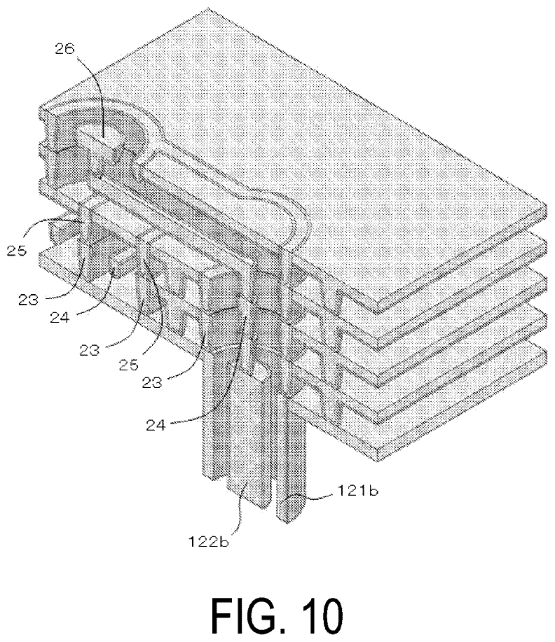

A wiring board according to yet another embodiment of the present disclosure will be described with reference to FIGS. 9 and 10. FIG. 9 is an explanatory diagram illustrating a cross section of a wiring board 400 according to a fourth embodiment of the present disclosure. FIG. 10 is a perspective view schematically illustrating only a conductor portion in the wiring board illustrated in FIG. 9. In the wiring board 400 illustrated in FIG. 9, components the same as and/or similar to those of the wiring board 100 according to the first embodiment are denoted by the same reference signs, and detailed description is omitted.

In the wiring board 100 according to the first embodiment, the bottom surface of the first wiring conductor 23 located in the first groove G1 (the bottom surface of the second underlying metal layer 22c) are located near the first upper surface f1 of the first insulating layer 21a. On the other hand, in the wiring board 400 according to the fourth embodiment, a bottom surface of a first wiring conductor 23 (a bottom surface of a second underlying metal layer 22c) located on a first groove G1 are in contact with a lower layer conductor (corresponding to a core conductor layer 12a in the wiring board 400 illustrated in FIG. 9). As described above, the wiring board 400 according to the fourth embodiment differs from the wiring board 100 according to the first embodiment in the arrangement of the first wiring conductor 23.

In the wiring board 400 according to the fourth embodiment, the bottom surface of the first wiring conductor 23 located in the first groove G1 is in contact with the lower layer conductor, and thus the shielding performance of a second wiring conductor 24 functioning as a wiring conductor for signals is improved. That is, the second wiring conductor 24 is shielded by the first wiring conductors 23 that are located so as to sandwich the second wiring conductor 24.

In order to bring the bottom surface of the first wiring conductor 23 located in the first groove G1 into contact with the lower layer conductor, the above-described manufacturing method (steps (a) to (f)) may further include the step (step (g)) of forming a lower conductor layer on a surface of the first insulating layer 21a opposite to the first surface. The lower conductor layer corresponds to the core conductor layer 12a in the wiring board 400 illustrated in FIG. 9. After the lower conductor layer is formed in step (g), the first groove G1 is formed to have a depth reaching the lower conductor layer. Then, a conductor that will become the first wiring conductor 23 may be formed in the first groove G1.

As illustrated in FIG. 9, the wiring board 400 according to the fourth embodiment may further include a third insulating layer 21c, a fourth insulating layer 21d, a third groove G3, and a third wiring conductor 25. The third insulating layer 21c is located on a second upper surface f2 of a second insulating layer 21b and includes a third upper surface f3. The fourth insulating layer 21d is located on the third upper surface f3 of the third insulating layer 21c and includes a fourth upper surface f4. The third groove G3 includes a third inner surface recessed from the fourth upper surface f4 of the fourth insulating layer 21d toward the third insulating layer 21c. The third wiring conductor 25 includes a second wide pattern WP2 located from the third groove G3 to the third upper surface and has a width of not less than 150 μm.

Examples of resins for the third insulating layer 21c and the fourth insulating layer 21d also include resins the same as and/or similar to those forming the above-described first insulating layer 21a. One of the resins may be used alone, or two or more of the resins may be used in a combination. The insulation particles the same as and/or similar to those of the first insulating layer 21a may be dispersed in the third insulating layer 21c and the fourth insulating layer 21d. The thickness of the third insulating layer 21c and the thickness of the fourth insulating layer 21d are not limited. For example, the thickness of the fourth insulating layer 21d may be less than the thickness of the third insulating layer 21c. The third insulating layer 21c has a thickness of, for example, not less than 10 μm and not more than 50 μm. The fourth insulating layer 21d has a thickness of, for example, not less than 5 μm and not more than 25 μm.

The third wiring conductor 25 includes an underlying metal layer and an electrolytic plating layer, as the same as or similar to the above-described first wiring conductor 23. In the above description of these layers, the first insulating layer 21a corresponds to the third insulating layer 21c, the first upper surface f1 corresponds to the third upper surface, the first groove G1 corresponds to the third groove G3, and the first inner surface n1 corresponds to the third inner surface.

The third wiring conductor 25 located on the third groove G3 is in contact with the first wiring conductor 23. In a cross-sectional view in a thickness direction of the wiring board, a portion of the second wiring conductor 24 is surrounded by the lower layer conductor (corresponding to the core conductor layer 12a in the wiring board 400 illustrated in FIG. 9), the first wiring conductor 23, and the third wiring conductor 25. That is, a coaxial wiring structure is formed in a build-up layer 20. In the wiring board 400 according to the fourth embodiment includes such a coaxial wiring structure formed therein, the shielding performance of the second wiring conductor 24 functioning as a wiring conductor for signals is further improved.

In order to further include the third insulating layer 21c, the fourth insulating layer 21d, the third groove G3, and the third wiring conductor 25, the following steps (h) to (l) may be further included in addition to the above-described manufacturing method (steps (a) to (f)).
(h) forming the third insulating layer 21c including the third upper surface on the second upper surface f2.
(i) forming the second wide pattern WP2 on the third upper surface, the second wide pattern WP2 having a width of not less than 150 μm.
(j) forming the fourth insulating layer 21d covering the third upper surface and the second wide pattern WP2 and including a fourth upper surface.
(k) forming the third groove G3 recessed from the fourth upper surface toward the third insulating layer 21c and reaching the first wiring conductor 23, the third groove G3 being in contact with side surfaces of the second wide pattern WP2 and being formed on both sides of the second wiring conductor 24 in a plane perspective view.
(l) forming the third wiring conductors 25 located from the third groove G3 to the third upper surface and including the second wide pattern WP2, the third wiring conductors 25 being in partial contact with the first wiring conductor 23 and being formed on both sides of the second wiring conductor 24 in a plane perspective view.

The method (steps (h) to (l)) of forming the third insulating layer 21c, the fourth insulating layer 21d, the second wide pattern WP2, the third groove G3, and the third wiring conductor 25 may be performed in accordance with the method (steps) of forming the first insulating layer 21a, the second insulating layer 21b, the wide patterns WP, the first groove G1, and the first wiring conductor 23 described above.

As illustrated in FIG. 9, the wiring board 400 according to the fourth embodiment may further include a fifth insulating layer 21e including a plurality of electrodes 26 on a side of the first upper surface f1. The fifth insulating layer 21e may also be made of resins the same as and/or similar to those forming the first insulating layer 21a. One of the resins may be used alone, or two or more of the resins may be used in a combination. The insulating particles the same as and/or similar to those of the first insulating layer 21a may be dispersed in the fifth insulating layer 21e. The thickness of the fifth insulating layer 21e is not limited. The fifth insulating layer 21e has the thickness of, for example, not less than 5 μm and not more than 25 μm

As illustrated in FIG. 9, in the wiring board 400 according to the fourth embodiment, the lower layer conductor (corresponding to the core conductor layer 12a) may further include a first through-hole conductor 121b having a cylindrical shape, and a second through-hole conductor 122b located inside the first through-hole conductor 121b and spaced apart from the first through-hole conductor 121b in a plan view. The first through-hole conductor 121b and the second through-hole conductor 122b are, as the same as or similar to the above-described through-hole conductor 12b, located in a through hole TH that penetrates a core insulating layer 11 vertically. The first through-hole conductor 121b and the second through-hole conductor 122b electrically connect the core conductor layer 12a and the build-up conductor layer 22, which are located on upper and lower surfaces of the core insulating layer 11. The first through-hole conductor 121b and the second through-hole conductor 122b are also conductors made of metal plating such as copper plating, as the same as or similar to the above-described through-hole conductor 12b.

The first through-hole conductor 121b has a cylindrical shape and is formed on an inner wall surface of the through hole TH. The second through-hole conductor 122b is located inside the first through-hole conductor 121b so as to be surrounded by the first through-hole conductor 121b. The second through-hole conductor 122b has a columnar shape such as a cylindrical shape. By the first through-hole conductor 121b and the second through-hole conductor 122b having such a structure, for example, when the first through-hole conductor 121b is a grounding conductor and the second through-hole conductor 122b is a conductor for signals, the second through-hole conductor 122b can be shielded by the first through-hole conductor 121b, and the signal transmission characteristics are improved.

A filling resin 11a is filled between the first through-hole conductor 121b and the second through-hole conductor 122b. The filling resin 11a is not limited, and examples thereof include, for example, an epoxy resin, a bismaleimide-triazine resin, a polyimide resin, a polyphenylene ether resin, and a liquid crystal polymer.

The first through-hole conductor 121b is electrically connected to the first wiring conductor 23 and the third wiring conductor 25. Among the plurality of electrodes 26, at least one electrode 26 is electrically connected to the second through-hole conductor 122b via the second wiring conductor 24. The electrode 26 is a portion of the build-up conductor layer 22 exposed from an opening portion of the solder resist layer 30. Among the plurality of electrodes 26, at least two electrodes 26 may be electrically connected via the second wiring conductor 24.

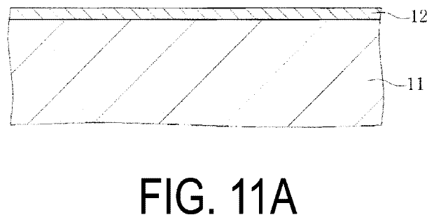

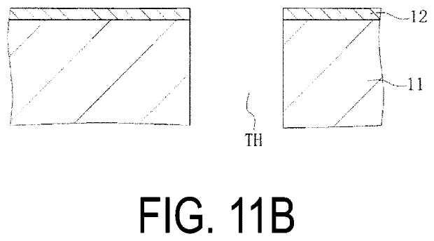

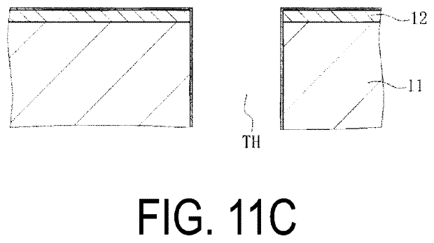

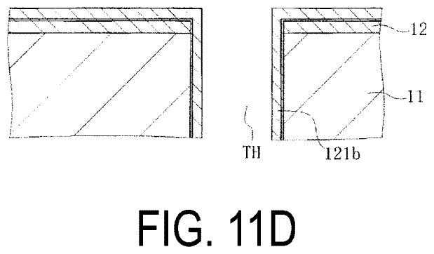

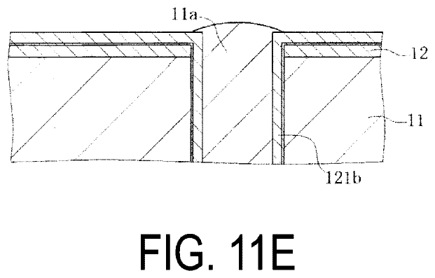

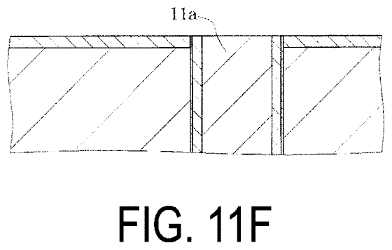

Hereinafter, one embodiment of a method for manufacturing the wiring board 400 according to the fourth embodiment will be described with reference to FIGS. 11 to 15. FIGS. 11 to 15 are explanatory diagrams illustrating manufacturing processes of the wiring board according to the fourth embodiment of the present disclosure.

First, the core substrate 10 is prepared. As illustrated in FIG. 11A, a laminate body of the core insulating layer 11 and a core conductor 12 is prepared. Then, as illustrated in FIG. 11B, the through hole TH is formed. The through hole TH is formed by a general method using drilling, a laser machining process, or the like. Then, as illustrated in FIG. 11C, the electroless copper plating is deposited on the surface of the core conductor 12 and the inner wall surface of the through hole TH, and then, as illustrated in FIG. 11D, the electrolytic copper plating is deposited. The electrolytic copper plating is deposited so as not to fill the through hole TH.

Then, as illustrated in FIG. 11E, the through hole TH is filled with the filling resin 11a, and as illustrated in FIG. 11F, the filling resin 11a protruding from the through hole TH is removed. The filling resin 11a is removed, for example, by grinding. When the filling resin 11a is removed, the electroless copper plating and the electrolytic copper plating formed on the portions other than the inner wall surface of the through hole TH may be removed or may remain. In this way, the first through-hole conductor 121b is formed on the inner wall surface of the through hole TH.

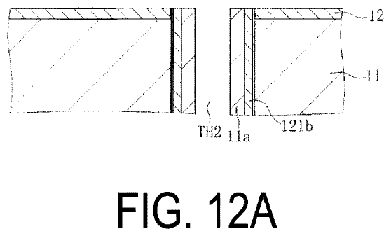

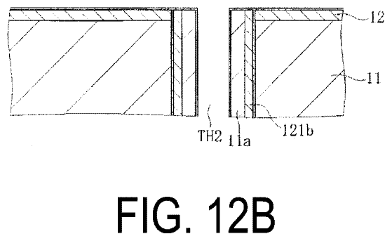

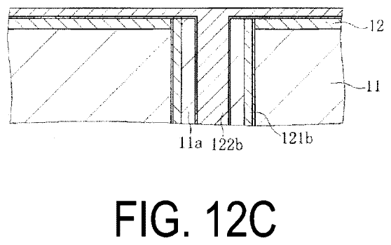

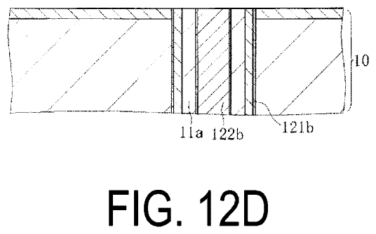

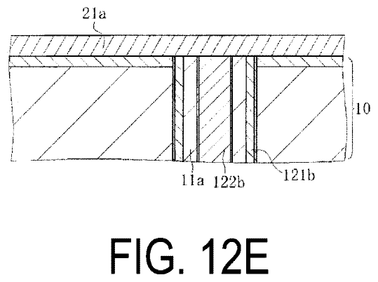

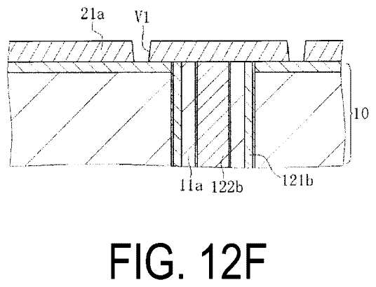

Then, as illustrated in FIG. 12A, a second through hole TH2 is formed in the center portion of the filling resin 11a so as to penetrate through the upper and lower surfaces in the thickness direction. Then, as illustrated in FIG. 12B, the electroless copper plating is deposited on the surface of the core conductor 12 and the inner wall surface of the second through hole TH2, and then, as illustrated in FIG. 12C, the electrolytic copper plating is deposited. The electrolytic copper plating is deposited so as to fill the second through hole TH2. Then, as illustrated in FIG. 12D, the electroless copper plating and the electrolytic copper plating located on the surface of the core conductor 12 are removed, for example, by polishing or the like. In this way, the second through-hole conductor 122b is formed in the second through hole TH2, and the core substrate 10 is formed.

Then, as illustrated in FIG. 12E, the first insulating layer 21a is formed on the surface of the core substrate 10, and as illustrated in FIG. 12F, a via hole V1 that penetrates the first insulating layer 21a is formed at a desired position. The via hole V1 is formed by a laser machining process as described above.

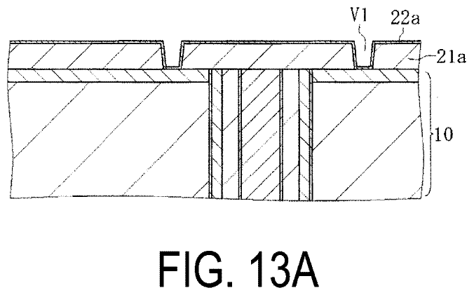

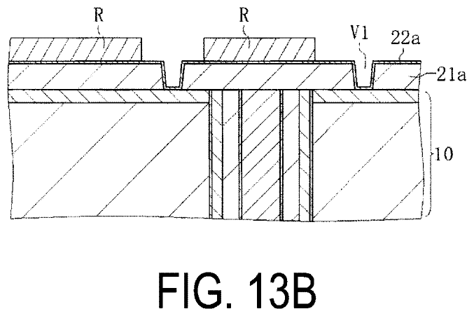

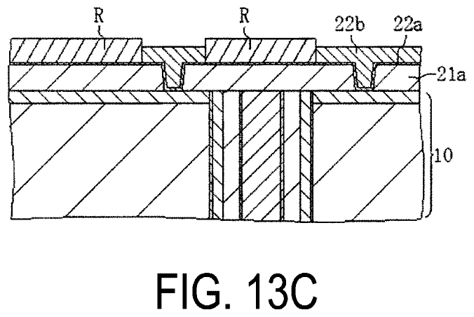

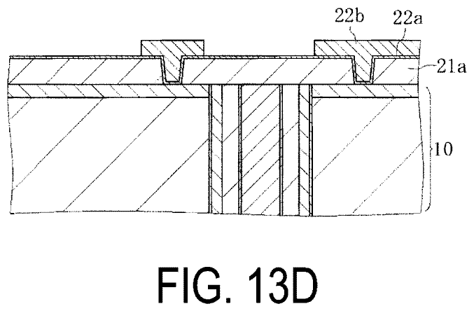

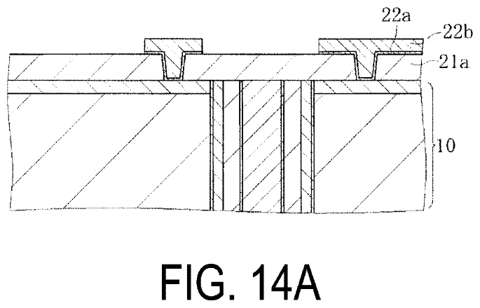

Then, as illustrated in FIG. 13A, the electroless copper plating is deposited on the surface of the first insulating layer 21a and an inner wall surface of the via hole V1. This electroless copper plating corresponds to a first underlying metal layer 22a. Then, as illustrated in FIG. 13B, a portion where the electrolytic copper plating (corresponding to a first electrolytic plating layer 22b) is not formed is covered with a resist R, and as illustrated in FIG. 13C, the electrolytic copper plating is deposited to form the first electrolytic plating layer 22b. Then, as illustrated in FIG. 13D, the resist R is removed.

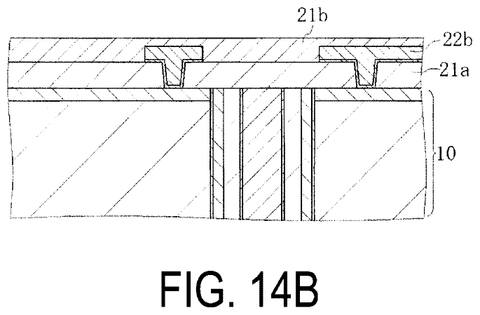

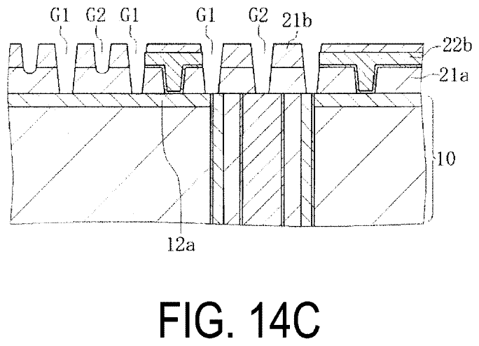

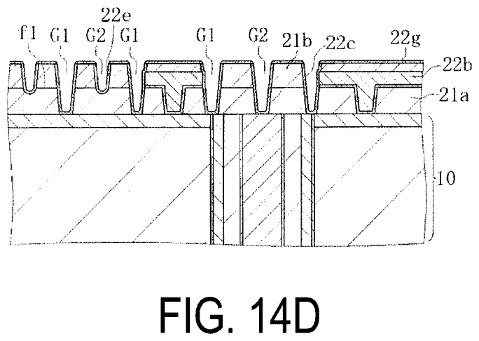

Then, as illustrated in FIG. 14A, after removing the resist R, a portion of the electroless copper plating (the first underlying metal layer 22a) that had been covered with the resist R is removed. The first underlying metal layer 22a is removed, for example, by etching or the like. Then, as illustrated in FIG. 14B, the second insulating layer 21b is formed so as to cover the surface of the first insulating layer 21a and the first electrolytic plating layer 22b.

Then, as illustrated in FIG. 14C, the first groove G1 and a second groove G2 are formed. The first groove G1 is formed so as to penetrate to the lower layer conductor (core conductor layer 12a) located on the side opposite to the first upper surface f1 of the first insulating layer 21a. The second groove G2 is formed such that the bottom surface thereof is located near the first upper surface f1 of the first insulating layer 21a. In terms of insulation reliability, a bottom surface of the second groove G2 is preferably separated from the lower layer conductor by not less than 10 μm, for example. The first groove G1 and the second groove G2 are formed by a laser machining process as described above. The first groove G1 and the second groove G2 are formed, for example, by changing the number of laser shots.

Then, as illustrated in FIG. 14D, the electroless copper plating is deposited on the surface of the second insulating layer 21b, an inner wall surface of the first groove G1, and an inner wall surface of the second groove G2. The electroless copper plating corresponds to the second underlying metal layer 22c and the third underlying metal layer 22e. That is, the electroless copper plating located on the inner wall surface of the first groove G1 corresponds to the second underlying metal layer 22c, and the electroless copper plating located on the inner wall surface of the second groove G2 corresponds to the third underlying metal layer 22e.

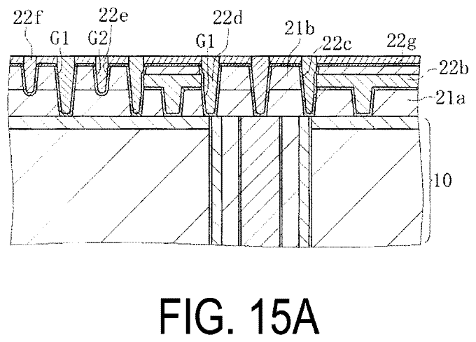

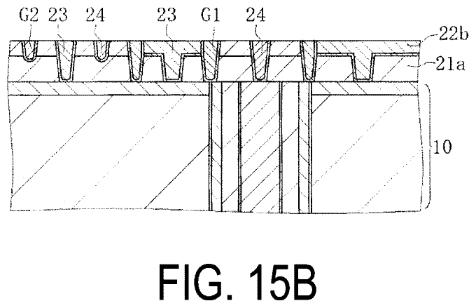

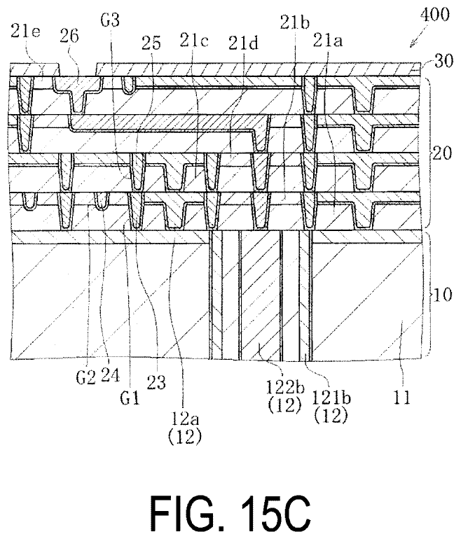

Then, as illustrated in FIG. 15A, the electrolytic copper plating is deposited so as to fill the first groove G1 and the second groove G2. The electrolytic copper plating located in the first groove G1 corresponds to the second electrolytic plating layer 22d, and the electrolytic copper plating located in the second groove G2 corresponds to the third electrolytic plating layer 22f. Then, as illustrated in FIG. 15B, the excess electrolytic copper plating and the excess electroless plating protruding from the first groove G1 and the second groove G2 are removed. The electrolytic copper plating and the electroless plating may be removed, for example, by polishing or the like. In this manner, the first wiring conductor 23 is formed in the first groove G1, and the second wiring conductor 24 is formed in the second groove G2.

By repeating FIGS. 12E to 15B a desired number of times and forming a solder resist including an opening in a portion where the electrode 26 is to be exposed on the surface, the wiring board 400 according to the fourth embodiment is obtained, as illustrated in FIG. 15C.

In each of the wiring board 100 according to the first embodiment, the wiring board 200 according to the second embodiment, the wiring board 300 according to the third embodiment, and the wiring board 400 according to the fourth embodiment, the build-up layer 20 is located on the upper surface side of the core substrate 10. In the wiring board according to the present disclosure, the build-up layer 20 may be located on the lower surface side of the core substrate 10. In the build-up layer 20 located on the lower surface side of the core substrate 10, the upper surface such as the “first upper surface f1” and the “second upper surface f2” corresponds to the lower surface. However, when the top and bottom of the wiring board are rotated by 180 degrees, the upper surface side and the lower surface side of the core substrate 10 are reversed, and therefore, “first upper surface f1” and “second upper surface f2” are referred to as upper surfaces. That is, in the present specification, the surface of each layer of the build-up layer 20 on the side far from the core substrate 10 is referred to as the “upper surface”.

The invention according to the present disclosure is not limited to the above-described embodiments, and various changes or improvements can be made within the scope of the present disclosure described in (1) and (10) below.
(1) A wiring board according to the present disclosure includes a first insulating layer including a first upper surface, a second insulating layer located on the first upper surface and including a second upper surface, a first groove and a second groove recessed from the second upper surface toward the first insulating layer, the first groove including a first inner surface, and the second groove including a second inner surface, a first wiring conductor located from the first groove to the first upper surface and including a wide pattern having a width of not less than 150 μm, and a second wiring conductor located in the second groove and including a narrow pattern having a width of not more than 15 μm. The first wiring conductor includes a first underlying metal layer located on the first upper surface, a first electrolytic plating layer located on the first underlying metal layer and including a side surface forming a portion of the first inner surface, a second underlying metal layer located on the first inner surface and connected to the side surface of the first electrolytic plating layer, and a second electrolytic plating layer located on the second underlying metal layer and filled into the first groove. The second wiring conductor includes a third underlying metal layer located on the second inner surface, and a third electrolytic plating layer located on the third underlying metal layer and filled into the second groove.

With respect to the embodiment of the present disclosure, the embodiments described in (2) to (9) and (11) to (16) below are further disclosed.
(2) In the wiring board according to the above (1), the side surface of the first electrolytic plating layer has an arithmetic mean roughness Ra of not less than 150 nm and not more than 300 nm.
(3) In the wiring board according to the above (1) or (2), at least one of the first inner surface and/or the second inner surface has an arithmetic mean roughness Ra of not less than 50 nm and not more than 100 nm.
(4) In the wiring board according to any one of the above (1) to (3), the depth of the second groove is less than the thickness of the second insulating layer.
(5) In the wiring board according to any one of the above (1) to (4), at least a portion of a surface of the first electrolytic plating layer is covered with the second insulating layer.
(6) The wiring board according to any one of the above (1) to (5) further includes a lower layer conductor located on a surface opposite to the first upper surface of the first insulating layer. The first wiring conductor located in the first groove is in contact with the lower layer conductor.
(7) The wiring board according to the above (6) further includes a third insulating layer located on the second upper surface and including a third upper surface, a fourth insulating layer located on the third upper surface and including a fourth upper surface, a third groove including a third inner surface recessed from the fourth upper surface toward the third insulating layer, and a third wiring conductor located from the third groove to the third upper surface and including a second wide pattern having a width of not less than 150 μm. The third wiring conductor located in the third groove is in contact with the first wiring conductor. In a cross-sectional view in the thickness direction of the wiring board, a portion of the second wiring conductor is surrounded by the lower layer conductor, the first wiring conductor, and the third wiring conductor.
(8) The wiring board according to the above (7) further includes a fifth insulating layer including a plurality of electrodes on the first upper surface side. The lower layer conductor further includes a first through-hole conductor having a cylindrical shape, and a second through-hole conductor located inside the first through-hole conductor and spaced apart from the first through-hole conductor in a plan view. The first through-hole conductor is electrically connected to the first wiring conductor and the third wiring conductor. Among the plurality of electrodes, at least one electrode and/or the second through-hole conductor are electrically connected via the second wiring conductor.
(9) In the wiring board according to the above (8), among the plurality of electrodes, at least two electrodes are electrically connected via the second wiring conductor.
(10) A method for manufacturing a wiring board according to the present disclosure includes forming a first insulating layer including a first upper surface, forming a wide pattern on the first upper surface, the wide pattern including a first underlying metal layer and a first electrolytic plating layer located on the first underlying metal layer, the wide pattern having a width of not less than 150 μm, forming a second insulating layer covering the first upper surface and the wide pattern, the second insulating layer including a second upper surface, forming a first groove and a second groove recessed from the second upper surface toward the first insulating layer, the first groove including a first inner surface in contact with a side surface of the wide pattern, and the second groove including a second inner surface spaced apart from the wide pattern, forming a second underlying metal layer covering the first inner surface, a third underlying metal layer covering the second inner surface, a fourth underlying metal layer covering the second upper surface and being continuous with the second underlying metal layer and the third underlying metal layer, a second electrolytic plating layer located on the second underlying metal layer, the second electrolytic plating layer having a thickness to fill the first groove, a third electrolytic plating layer located on the third underlying metal layer, the third electrolytic plating layer having a thickness to fill the second groove, and a fourth electrolytic plating layer located on the fourth underlying metal layer and continuous with the second electrolytic plating layer and the third electrolytic plating layer, and forming a first wiring conductor located from the first groove to the first surface and including the wide pattern, a second wiring conductor located in the second groove and including a narrow pattern having a width of not more than 15 μm, by at least removing the fourth underlying metal layer and the fourth electrolytic plating layer located on the second upper surface.
(11) In the manufacturing method according to the above (10), in the forming a first wiring conductor, a roughening treatment is performed on the side surface of the first electrolytic plating layer so that an arithmetic mean roughness Ra becomes not less than 150 nm and not more than 300 nm.
(12) In the manufacturing method according to the above (10) or (11), in the forming a first groove and a second groove, the groove forming process is performed in which the first inner surface and the second inner surface, excluding the side surface of the wide pattern, have an arithmetic mean roughness Ra of not less than 50 nm and not more than 100 nm.
(13) In the manufacturing method according to the above (10) to (12), in the forming a first groove and a second groove, the first groove is formed to have the depth less than the thickness of the second insulating layer.
(14) In the manufacturing method according to any one of the above (10) to (13), in the forming a first wiring conductor and a second wiring conductor, at least the fourth underlying metal layer and the fourth electrolytic plating layer located on the second insulating layer are removed for at least a portion of the surface of the first wiring conductor being not exposed.
(15) The manufacturing method according to any one of the above (10) to (14) further includes forming a lower conductor layer on a surface of the first insulating layer opposite to the first surface. The first groove is formed to have a depth reaching the lower conductor layer.
(16) The manufacturing method according to the above (15) further includes forming a third insulating layer including a third upper surface on the second upper surface, forming a second wide pattern having a width of not less than 150 μm on the third upper surface, forming a fourth insulating layer covering the third upper surface and the second wide pattern and including a fourth upper surface, forming a third groove recessed from the fourth upper surface toward the third insulating layer and reaching the first wiring conductor, the third groove being in contact with side surfaces of the second wide pattern and being formed on both sides of the second wiring conductor, and forming third wiring conductors located from the third groove to the third upper surface and including the second wide pattern, the third wiring conductors being in partial contact with the first wiring conductor and being formed on both sides of the second wiring conductor.

### REFERENCE SIGNS

10 Core substrate
11 Core insulating layer
12 Core conductor
12a Core conductor layer
12b Through-hole conductor
20 Build-up layer
21 Build-up insulating layer
21a First insulating layer
21b Second insulating layer
21c Third insulating layer
21d Fourth insulating layer
21e Fifth insulating layer
22 Build-up conductor layer
22a First underlying metal layer
22b First electrolytic plating layer
22c Second underlying metal layer
22d Second electrolytic plating layer
22e Third underlying metal layer
22f Third electrolytic plating layer
22g Fourth underlying metal layer
22h Fourth electrolytic plating layer
23 First wiring conductor
24 Second wiring conductor
25 Third wiring conductor
26 Electrode
30 Solder resist layer
100, 200, 300, 400 Wiring board
G1 First groove
G2 Second groove
G3 Third groove
NP Narrow pattern
WP Wide pattern
WP2 Second wide pattern

1. A wiring board comprising:
a first insulating layer comprising a first upper surface;
a second insulating layer located on the first upper surface and comprising a second upper surface;
a first groove comprising a first inner surface recessed from the second upper surface toward the first insulating layer;
a second groove comprising a second inner surface recessed from the second upper surface toward the first insulating layer;
a first wiring conductor located from the first groove to the first upper surface and comprising a wide pattern having a width of not less than 150 μm; and
a second wiring conductor located in the second groove and comprising a narrow pattern having a width of not more than 15 μm, wherein
the first wiring conductor comprises
a first underlying metal layer located on the first upper surface,
a first electrolytic plating layer located on the first underlying metal layer and comprising a side surface forming a portion of the first inner surface,
a second underlying metal layer located on the first inner surface and connected to the side surface of the first electrolytic plating layer, and
a second electrolytic plating layer located on the second underlying metal layer and filled into the first groove, and
the second wiring conductor comprises
a third underlying metal layer located on the second inner surface, and
a third electrolytic plating layer located on the third underlying metal layer and filled into the second groove.

2. The wiring board according to claim 1, wherein
the side surface of the first electrolytic plating layer has an arithmetic mean roughness Ra not less than 150 nm and not more than 300 nm.

3. The wiring board according to claim 1, wherein
at least one of the first inner surface and/or the second inner surface has an arithmetic mean roughness Ra not less than 50 nm and not more than 100 nm.

4. The wiring board according to claim 1, wherein
a depth of the second groove is less than a thickness of the second insulating layer.

5. The wiring board according to claim 1, wherein
at least a portion of a surface of the first electrolytic plating layer is covered by the second insulating layer.

6. The wiring board according to claim 1, further comprising:
a lower layer conductor located on a surface of the first insulating layer opposite to the first upper surface, wherein
the first wiring conductor located in the first groove is in contact with the lower layer conductor.

7. The wiring board according to claim 6, further comprising:
a third insulating layer located on the second upper surface and comprising a third upper surface;
a fourth insulating layer located on the third upper surface and comprising a fourth upper surface;
a third groove comprising a third inner surface recessed from the fourth upper surface toward the third insulating layer side; and
a third wiring conductor located from the third groove to the third upper surface and comprising a second wide pattern having a width of not less than 150 μm, wherein
the third wiring conductor located in the third groove is in contact with the first wiring conductor, and
the second wiring conductor includes a portion being surrounded by the lower layer conductor, the first wiring conductor, and the third wiring conductor in a cross-sectional view in the thickness direction of the wiring board.

8. The wiring board according to claim 7, further comprising:
a fifth insulating layer comprising a plurality of electrodes, wherein
the lower layer conductor further comprises a first through-hole conductor having a cylindrical shape, and a second through-hole conductor located inside the first through-hole conductor in a plan view and spaced apart from the first through-hole conductor,
the first through-hole conductor is electrically connected to the first wiring conductor and the third wiring conductor, and
at least one electrode among the plurality of electrodes is electrically connected to the second through-hole conductor via the second wiring conductor.

9. The wiring board according to claim 8, wherein
at least two electrodes among the plurality of electrodes are electrically connected to each other via the second wiring conductor.

10. A method for manufacturing a wiring board, comprising:
forming a first insulating layer comprising a first upper surface;
forming a wide pattern on the first upper surface, the wide pattern comprising a first underlying metal layer and a first electrolytic plating layer located on the first underlying metal layer, the wide pattern having a width of not less than 150 μm;
forming a second insulating layer covering the first upper surface and the wide pattern, the second insulating layer comprising a second upper surface;
forming a first groove and a second groove recessed from the second upper surface toward the first insulating layer side, the first groove comprising a first inner surface in contact with a side surface of the wide pattern, the second groove comprising a second inner surface spaced apart from the wide pattern;
forming a second underlying metal layer covering the first inner surface, a third underlying metal layer covering the second inner surface, a fourth underlying metal layer covering the second upper surface and being continuous with the second underlying metal layer and the third underlying metal layer, a second electrolytic plating layer located on the second underlying metal layer, the second electrolytic plating layer having a thickness to fill the first groove, a third electrolytic plating layer located on the third underlying metal layer, the third electrolytic plating layer having a thickness to fill the second groove, and a fourth electrolytic plating layer located on the fourth underlying metal layer and continuous with the second electrolytic plating layer and the third electrolytic plating layer; and
forming a first wiring conductor located from the first groove to the first upper surface and comprising the wide pattern, a second wiring conductor located in the second groove and comprising thea narrow pattern having a width of not more than 15 μm, by at least removing the fourth underlying metal layer and the fourth electrolytic plating layer located on the second upper surface.

11. The method for manufacturing according to claim 10, wherein
in the forming a first wiring conductor, a roughening treatment is performed on a side surface of the first electrolytic plating layer, and thus the side surface has an arithmetic mean roughness Ra not less than 150 nm and not more than 300 nm.

12. The method for manufacturing according to claim 10 or 11, wherein
in the forming a first groove and a second groove, a groove forming process is performed on the first inner surface and the second inner surface, excluding the side surface of the wide pattern, and thus the first inner surface and the second inner surface having an arithmetic mean roughness Ra not less than 50 nm and not more than 100 nm.

13. The method for manufacturing the wiring board according to claim 10, wherein
in the forming a first groove and a second groove, the first groove is formed with a depth less than a thickness of the second insulating layer.

14. The method for manufacturing the wiring board according to claim 10, wherein
in the forming a first wiring conductor and a second wiring conductor, at least the fourth underlying metal layer and the fourth electrolytic plating layer located on the second insulating layer are removed, with at least a portion of a surface of the first wiring conductor remaining unexposed.

15. The method for manufacturing the wiring board according to claim 10, further comprising:
forming a lower conductor layer on a surface of the first insulating layer opposite to the first upper surface; and
forming the first groove with a depth reaching the lower conductor layer.

16. The method for manufacturing the wiring board according to claim 15, further comprising:
forming a third insulating layer on the second upper surface, the third insulating layer comprising a third upper surface;
forming a second wide pattern having a width of not less than 150 μm on the third upper surface;
forming a fourth insulating layer covering the third upper surface and the second wide pattern, the fourth insulating layer comprising a fourth upper surface;
forming a third groove recessed from the fourth upper surface toward the third insulating layer and reaching the first wiring conductor, the third groove being in contact with a side surface of the second wide pattern and being formed on both sides of the second wiring conductor; and
forming a third wiring conductor located from the third groove to the third upper surface and comprising the second wide pattern, the third wiring conductor being in partial contact with the first wiring conductor and being formed on both sides of the second wiring conductor.
